(19) United States
(12) Patent Application Publication
(10) Pub. No.: US 2007/0187682 A1
(43) Pub. Date: Aug. 16, 2007

(54) Semiconductor device having fin-type effect transistor

(75) Inventors: Kiyoshi Takeuchi, Minato-ku (JP); Koji Watanabe, Minato-ku (JP); Koichi Terashima, Minato-ku (JP); Atsushi Ogura, Minato-ku (JP); Toru Tatsumi, Minato-ku (JP); Koichi Takeda, Minato-ku (JP); Masahiro Nomura, Minato-ku (JP); Masayasu Tanaka, Minato-ku (JP); Shigeharu Yamagami, Minato-ku (JP); Hitoshi Wakabayashi, Minato-ku (JP)

Correspondence Address: SUGHRUE MION, PLLC, 2100 PENNSYLVANIA AVENUE, N.W., SUITE 800, WASHINGTON, DC, 20037, US

(73) Assignee: NEC Corporation

(21) Appl. No.: 10/569,451

(22) PCT Filed: Aug. 27, 2004
(86) PCT No.: PCT/JP04/12385

§ 371 Date: Sep. 26, 2006

(30) Foreign Application Priority Data
Aug. 28, 2003 (JP) 2003-304753
Aug. 12, 2004 (JP) 2004-235346

(51) Int. Cl. H01L 29/04

(52) U.S. Cl. 257/64

(57) ABSTRACT

There is provided a semiconductor device comprising an n-type and a p-type field effect transistors, meeting the conditions that in terms of a crystal orientation of the protruding semiconductor region constituting the n-type field effect transistor, its plane parallel to the substrate is substantially a {100} plane and its side surface is a {100} plane substantially orthogonal to the {100} plane, and that in terms of a crystal orientation of the protruding semiconductor region constituting the p-type field effect transistor, its plane parallel to the substrate is substantially a {100} plane and its side surface is a {110} plane substantially orthogonal to the {100} plane.

### TECHNICAL FIELD

This invention relates to a semiconductor device having a fin-type field effect transistor with higher carrier mobility.

### BACKGROUND OF THE INVENTION

There has been developed a fin-type MISFET having a protrusion consisting of a semiconductor region in which a main channel is formed in a plane (a side surface of the protrusion) substantially perpendicular to a substrate, for preventing a short channel effect associated with size reduction. Japanese Patent Application No. 1989-8670 has disclosed a fin-type MISFET in which a part of a protrusion is a part of a silicon wafer substrate and a fin-type MISFET in which a part of a protrusion is a part of a monocrystal silicon layer in an SOI substrate. The structures of the former and the latter will be described with reference to FIGS. 12(a) and (b), respectively.

In the structure shown in FIG. 12(a), a part of a silicon wafer substrate 101 is a protrusion 103, and a gate electrode 105 extends to both sides, passing over the top of the protrusion 103. In this protrusion 103, a channel is formed below an insulating film 104 under the gate electrode. A channel width corresponds to twice as large as the height of the protrusion 103 (h), and a gate length corresponds to the width of the gate electrode 105 (L). The gate electrode 105 is formed on an insulating film 102 formed in this trench such that it strides over the protrusion 103.

In the structure shown in FIG. 12(b), an SOI substrate consisting of a silicon wafer substrate 111, an insulating film 112 and a silicon monocrystal layer is prepared; the silicon monocrystal layer is patterned to form a protrusion 113; and then a gate electrode 115 is formed on the exposed insulating layer 112 such that the electrode strides over the protrusion 113. In this protrusion 113, a source and a drain regions are formed in both sides of the gate electrode, and a channel is formed below the insulating film 114 (the upper and the side surfaces of the protrusion 113) under the gate electrode. A channel width corresponds to the sum of twice as large as the height (a) and the width (b) of the protrusion 113, and a gate length corresponds to the width of the gate electrode 115 (L).

Thus, a fin-type MISFET has gates in both side surfaces of a semiconductor region where a channel is to be formed, and generally has a characteristic of good prevention of a short channel effect.

Japanese Patent Application No. 2002-118255 has disclosed a fin-type MOSFET having a plurality of semiconductor protrusions (semiconductor layer 213), for example, as illustrated in FIGS. 13(a) to (c). FIG. 13(b) is a cross-sectional view taken on line B-B of FIG. 13(a), while FIG. 13(c) is a cross-sectional view taken on line C-C of FIG. 13(a). This fin-type MOSFET has a plurality of semiconductor layers 213 constituted by a part of a well layer 211 in the silicon substrate 210; these are aligned in parallel with each other; and a gate electrode 216 strides over the centers of these protruding semiconductor layers. The gate electrode 216 is formed from the upper surface of the insulating film 214 and along the side of each of the semiconductor layers 213. An insulating film 218 intervenes between each protruding semiconductor layer and the gate electrode, and a channel 215 is formed in a protruding semiconductor layer under the gate electrode. Furthermore, each protruding semiconductor layer has source/drain regions, and in a region 212 under the source/drain regions 217 are formed a high-concentration dopant layer (punch-through stopper layer). There are formed upper-layer interconnects 229, 230 via an inter layer insulating film 226, and each contact plug 228 connects each upper-layer interconnects with the source/drain regions 217 and the gate electrode 216, respectively.

Japanese Patent Application No. 2001-298194 has disclosed a fin-type MOSFET, for example, as shown in FIGS. 14(a) and (b). This fin-type MOSFET is made from an SOI substrate consisting of a silicon substrate 301, an insulating layer 302 and a semiconductor layer (monocrystal silicon layer) 303, and the patterned semiconductor layer 303 is formed over the insulating layer 302. The semiconductor layer 303 has a plurality of openings 310 which are aligned, cutting across the semiconductor layer 303. These openings 310 are formed such that the insulating layer 302 is exposed during patterning the semiconductor layer 303. A gate electrode 305 is formed along the alignment direction of the openings 310; an insulating film intervenes between semiconductor layers (conduction path) 332 between the openings 310; and a channel is formed in the conduction path under the gate electrode. When the insulating film as the upper surface of the conduction path 332 is a gate insulating film as thin as the side insulating film, channels are formed in both sides and the upper surface of the semiconductor layer 332 under the gate electrode. In the semiconductor layer 303, both sides of the row of the openings 310 constitute source/drain regions 304.

In general preparation of such an MOSFET, a substrate whose crystal orientation is a {100} plane is diced (pelletized) in parallel with [110] into a chip. Therefore, a plane parallel to the substrate of the fin-type MOSFET has a crystal orientation of a {100} plane, while the side surface of the protrusion where a channel is to be formed generally has a crystal orientation of a {110} plane.

FIG. 2 is a plan view from <00-1> of a semiconductor device having an n-type MISFET 2001 and a p-type MISFET 2002 in which a plane parallel to a substrate has a crystal orientation of a (001) plane. For simplifying a layout, these MISFET are arranged such that the side surface of the protrusion of the n-type and the p-type MISFETs are mutually orthogonal (FIG. 2(a)) or parallel (FIG. 2(b)). In FIG. 2(a), the side surface of the protrusion of the n-type MISFET has a crystal orientation of a (−110) plane while the side surface of the protrusion of the p-type MISFET has a crystal orientation of a (110) plane. In FIG. 2(b), the side surfaces of the protrusions of both n-type and p-type MISFETs have a crystal orientation of a (−110) plane.

### SUMMARY OF THE INVENTION

Recently, there have been needs for accelerating a semiconductor device and developing a CMIS having improved carrier mobility properties. There has not been, however, investigated relationship between a delay index due to carrier mobility and a crystal orientation in the side surface of a semiconductor region in a fin-type CMIS.

In an aspect, an object of this invention is to optimize carrier mobility properties and accelerate a CMIS. In another aspect, an object of this invention is to optimizing acceleration of a CMIS and requirements in terms of a layout, taking these into account.

To solve the above problems, this invention has the following configuration. Specifically, according to an aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:

that in terms of a crystal orientation of the protruding semiconductor region constituting the n-type field effect transistor, its plane parallel to a substrate is substantially a {100} plane and its side surface is substantially a {100} plane orthogonal to the {100} plane, and that in terms of a crystal orientation of the protruding semiconductor region constituting the p-type field effect transistor, its plane parallel to the substrate is substantially a {100} plane.

According to another aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:

that in terms of a crystal orientation of the protruding semiconductor region constituting the p-type field effect transistor, its plane parallel to a substrate is substantially a {100} plane and its side surface is substantially a {110} plane orthogonal to the {100} plane, and that in terms of a crystal orientation of the protruding semiconductor region constituting the n-type field effect transistor, its plane parallel to the substrate is substantially a {100} plane and its side surface is substantially different from a {110} plane orthogonal to the {100} plane.

According to another aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:

that in terms of a crystal orientation of the protruding semiconductor region constituting the n-type field effect transistor, its plane parallel to a substrate is substantially a {100} plane and its side surface is substantially a {100} plane orthogonal to the {100} plane, and that in terms of a crystal orientation of the protruding semiconductor region constituting the p-type field effect transistor, its plane parallel to the substrate is substantially a {100} plane and its side surface is substantially a {110} plane orthogonal to the {100} plane.

According to another aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:

that in terms of a crystal orientation of the protruding semiconductor region constituting the n-type field effect transistor, its side surface is substantially a {100} plane, and that the side surface of the protruding semiconductor region constituting the p-type field effect transistor is substantially orthogonal to the {100} plane.

According to another aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:

that in terms of a crystal orientation of the protruding semiconductor region constituting the p-type field effect transistor, its side surface is substantially a {110} plane, and that the side surface of the protruding semiconductor region constituting the n-type field effect transistor is substantially orthogonal to the {110} plane, and a crystal orientation of the side surface is substantially different from a {110} plane.

According to another aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:

that in terms of a crystal orientation of the protruding semiconductor region constituting the n-type field effect transistor, its plane parallel to a substrate is substantially a {110} plane and its side surface is substantially a {100} plane orthogonal to the {110} plane, and that in terms of a crystal orientation of the protruding semiconductor region constituting the p-type field effect transistor, its plane parallel to the substrate is substantially a {110} plane and its side surface is substantially a {110} plane orthogonal to the {110} plane.

According to another aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:

that in terms of a crystal orientation of the protruding semiconductor region constituting the n-type field effect transistor, its plane parallel to a substrate is substantially a {100} plane and its side surface is substantially orthogonal to the {100} plane and different from a {110} plane, and that in terms of a crystal orientation of the protruding semiconductor region constituting the p-type field effect transistor, its plane parallel to the substrate is substantially a {100} plane and its side surface is substantially parallel or orthogonal to the side surface of the protruding semiconductor region constituting the n-type field effect transistor.

According to another aspect of the present invention, there is provided a semiconductor device comprising an n-type and a p-type field effect transistors having a protruding semiconductor region whose plane parallel to a substrate has a crystal orientation of a {100} or {100} plane of less than 10° off and which has a channel in its side surface, a gate electrode formed at least on the side surface via an insulating film, and a source and a drain regions formed in the semiconductor region such that the gate electrode is sandwiched by the regions, the n-type and the p-type field effect transistors have a crystal orientation obtained by independently fixing or rotating the side surfaces of the protrusions in the n-type and the p-type field effect transistors in a reference state to an angle of 0° to 90° both inclusive around the normal line of the substrate except the cases where both of the rotation angles of the n-type and the p-type field effect transistors are 0° or 90°, wherein a state where the side surface of the protrusion in the n-type field effect transistor and the side surface of the protrusion in the p-type field effect transistor are {110} or {110} planes of less than 10° off perpendicular to the substrate is the reference state.

According to another aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, the n-type and the p-type field effect transistors have a crystal orientation obtained by fixing or rotating the planes parallel to the substrate of the n-type and the p-type field effect transistors in the reference state and the side surface of the protrusion in the p-type field effect transistor in the reference state by an equal angle within the range of −45° to 45° both inclusive around the normal line of the side surface of the protrusion in the n-type field effect transistor, wherein a state where the planes of protrusions parallel to the substrate and the side surfaces of the protrusions in the n-type and the p-type field effect transistors are mutually orthogonal {100} or {100} planes of less than 10° off is the reference state.

According to another aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, the n-type and the p-type field effect transistors have a crystal orientation obtained by rotating the plane parallel to the substrate of the n-type and the p-type field effect transistors in the reference state and the side surface of the protrusion in the n-type field effect transistor in the reference state by an equal angle within the range of 90° or less around the normal line of the side surface of the protrusion in the p-type field effect transistor, wherein a state where the planes of protrusions parallel to the substrate and the side surfaces of the protrusions in the n-type and the p-type field effect transistors are mutually orthogonal, and are a {100} or {100} planes of less than 10° off and {110} planes, respectively, is the reference state.

According to another aspect of the present invention, there is provided a semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:

that in terms of a crystal orientation of the protruding semiconductor region constituting the n-type field effect transistor, its side surface is substantially a {100} plane, and that the side surface of the protruding semiconductor region constituting the p-type field effect transistor is substantially parallel to the {100} plane.

In the semiconductor device of this invention, a delay index of the CMIS and an arrangement of the MISFET in the light of a layout can be optimized by independently fixing or rotating the side surfaces of the protrusions in the n-type and the p-type MISFETs around the normal line of the substrate. In addition, a layout can be further facilitated and a delay index of the CMIS can be reduced by rotating the side surfaces of the protrusions in these MISFETs by an equal angle while keeping the arrangement that the side surfaces of the protrusions in the n-type and the p-type MISFETs are mutually orthogonal or parallel.

In the semiconductor device of this invention, a layout of the MISFET can be optimized and carrier mobility properties can be improved by fixing or rotating the planes parallel to the substrate of the n-type and the p-type MISFETs and the side surface of the protrusion in the p-type MISFET, centering around the normal line of the side surface of the protrusion in the n-type MISFET from the reference state that the side surfaces of the protrusions in the n-type and the p-type MISFET are arranged such that the planes parallel to the substrate of these MISFETs are mutually orthogonal {100} planes.

In the semiconductor device of this invention, MISFETs can be arranged with a higher density and carrier mobility properties can be improved by fixing or rotating the planes parallel to the substrate of the n-type and the p-type MISFETs and the side surface of the protrusion in the n-type MISFET centering around the normal line of the side surface of the protrusion in the p-type MISFET, from the reference state that a crystal orientation of the planes parallel to the substrate of the n-type and the p-type MISFETs is a {100} plane and a crystal orientation the side surfaces of the protrusions in the n-type and the p-type MISFETs is a {110} plane and these three surfaces and planes are mutually orthogonal.

In the semiconductor device of this invention, a low delay index of the CMIS and higher carrier mobility properties can be maintained, even when the planes parallel to the substrate of the n-type and the p-type MISFETs are rotated centering around the normal line of the side surfaces of the protrusions in the n-type and the p-type MISFETs from the reference state that the planes parallel to the substrate of the n-type and the p-type MISFETs are a {100} plane and the side surfaces of the protrusions in the n-type and the p-type MISFETs have the same crystal orientation, that is, a {100} plane perpendicular to the substrate.

### BRIEF DESCRIPTION OF THE DRAWINGS

FIG. 1(a) is a perspective view illustrating a semiconductor region according to this invention or the related art. FIG. 1(b) is a perspective view illustrating an MOS transistor according to this invention or the related art.

FIG. 2(a) shows a semiconductor device with an orthogonal arrangement according to the related art. FIG. 2(b) is a plan view illustrating a semiconductor device with a parallel arrangement according to the related art.

FIG. 3(a) is a plan view illustrating a semiconductor device with an orthogonal arrangement according to the present invention. FIG. 3(b) is a plan view illustrating a semiconductor device with a parallel arrangement according to the present invention.

FIG. 4(a) is a plan view illustrating a semiconductor device with an orthogonal arrangement according to the present invention. FIG. 4(b) is a plan view illustrating a semiconductor device with a parallel arrangement according to the present invention.

FIG. 5(a) is a plan view illustrating a semiconductor device with an orthogonal arrangement according to the present invention. FIG. 5(b) is a plan view illustrating a semiconductor device with a parallel arrangement according to the present invention.

FIG. 6 is a plan view illustrating a semiconductor device according to Embodiment 2 of this invention.

FIG. 7 is a plan view illustrating a semiconductor device according to Embodiment 3 of this invention.

FIG. 8(a) shows relationship between carrier mobility and a crystal orientation of the side surface of a protrusion in an n-type MISFET. FIG. 8(b) shows relationship between carrier mobility and a crystal orientation of the side surface of a protrusion in a p-type MISFET. FIG. 8(c) shows relationship between carrier mobility and a crystal orientation of the side surface of a protrusion in a p-type MISFET. FIG. 8(a) shows relationship between carrier mobility and a crystal orientation of the side surface of a protrusion in an n-type MISFET.

FIG. 9 shows relationship between a delay index of a CMIS and a crystal orientation of the side surface of a protrusion.

FIG. 10 shows a manufacturing process for a semiconductor device according to the present invention.

FIG. 11 shows a manufacturing process for a semiconductor device according to the present invention.

FIG. 12(a) is a perspective view illustrating an MISFET according to the related art. FIG. 12(b) is a perspective view illustrating an MISFET according to the related art.

FIG. 13(a) is a cross-sectional view of a multi-structure MISFET. FIG. 13(b) is a cross-sectional view of a multi-structure MISFET. FIG. 13(c) is a cross-sectional view of a multi-structure MISFET.

FIG. 14(a) is a cross-sectional view of a multi-structure MISFET. FIG. 14(b) is a cross-sectional view of a multi-structure MISFET.

FIG. 15 is a cross-sectional view of a tri-gate type MISFET according to the present invention.

FIG. 16 is a cross-sectional view of a double-gate type MISFET according to the present invention.

FIG. 17 is a cross-sectional view of a semiconductor device in which an MISFET of this invention and a planar type MISFET are mounted in combination.

FIG. 18 illustrates a crystal orientation and rotation.

FIG. 19 is a plan view illustrating a multi-structure MISFET according to the present invention.

### DETAILED DESCRIPTION OF THE INVENTION

In a conventional planar type MISFET where a channel is formed within a substrate directly beneath a gate electrode, the substrate is an isotropic {100} plane, so that mobility is unchanged when changing a direction of channel current flow within the substrate.

On the other hand, a channel is formed in the side surface of a semiconductor region in a fin-type MISFET, so that carrier mobility can be changed by rotating a crystal orientation of the side surface of a protrusion. For example, it is well-known that when forming a fin-type MISFET using a gate insulating film such as SiO₂, a (100) plane can reduce an interface state more than a (110) plane in terms of a crystal orientation of the side surface of a protruding semiconductor region. A fin-type MISFET in which a crystal orientation of the side surface is a (100) plane has common properties with a conventional planar type FET which uses a substrate for forming a (100) plane, and is, therefore, advantageous in that these FETs are interchangeable and can be easily designed.

Meanwhile, a semiconductor device has been more integrated, and thus, when using an n-type and a p-type MISFETs in combination, a CMIS typically having one pair of them must have higher carrier mobility properties. Furthermore, there has been an approach of constituting a logic circuit mainly using an n-type MISFET other than a CMIS (for example, a domino circuit), and in such a case, it is advantageous that the n-type MISFET has higher mobility.

Thus, we have investigated relationship between carrier mobility and the side surface of a protrusion in a semiconductor region in a fin-type MISFET and have achieved this invention. Specifically, this invention can realize acceleration of an n-type MISFET or CMIS by changing a crystal orientation in a semiconductor constituting a protruding semiconductor region (a plane parallel to the substrate of the protrusion, the side surface of the protrusion, or both of them), and acceleration of a CMIS and optimization of layout requirements.

Semiconductor Device

In a typical fin-type MISFET, a channel is formed at least in a part of the side surface of a protrusion directly beneath a gate electrode, and a channel-forming part is a channel region. A direction of channel current flow is parallel to the side surface of the protrusion and to the substrate. Therefore, by defining a crystal orientation parallel to the substrate and a crystal orientation of the side surface of the protrusion, a current direction is uniquely determined except its orientation (positive or negative). Although the side surface of the protrusion is formed to be substantially perpendicular to the substrate, it may be in a taper form where a width W of the semiconductor region varies from the upper part toward the lower part of the protrusion. Herein, an angle formed by the normal line of the substrate and the side surface of the protrusion is preferably 10° or less. When an angle formed by the side surface of the protrusion and the normal line of the substrate is within the range, similar properties to those in a case where the side surface of the protrusion is perpendicular to the substrate, and thus these cases can be regarded as being identical. As used in this invention including the appended claims, the phrase “substantially having a given crystal orientation” in terms of a crystal orientation of the side surface of the protrusion, shall include, besides a case where the side surface of the protrusion is perpendicular to the substrate, a case where it is in a taper form within 10° as described above.

In this invention, a “protruding semiconductor region” may be generally in any form as long as a surface substantially perpendicular to the substrate plane can be utilized as a channel region as described above. In this invention, a crystal orientation is defined, particularly in a channel region in a protruding semiconductor region (including a crystal orientation of the side surface of the protrusion). Therefore, source/drain regions may have any shape and any crystal orientation. Thus, the “side surface of a protrusion” as used herein means only a side surface where a channel is formed in the protruding semiconductor region. The protruding semiconductor region may protrude from a substrate such that it has a side surface in which a channel can be formed, and typically protrudes from an insulating film intervening between a semiconductor layer constituting a device and a substrate.

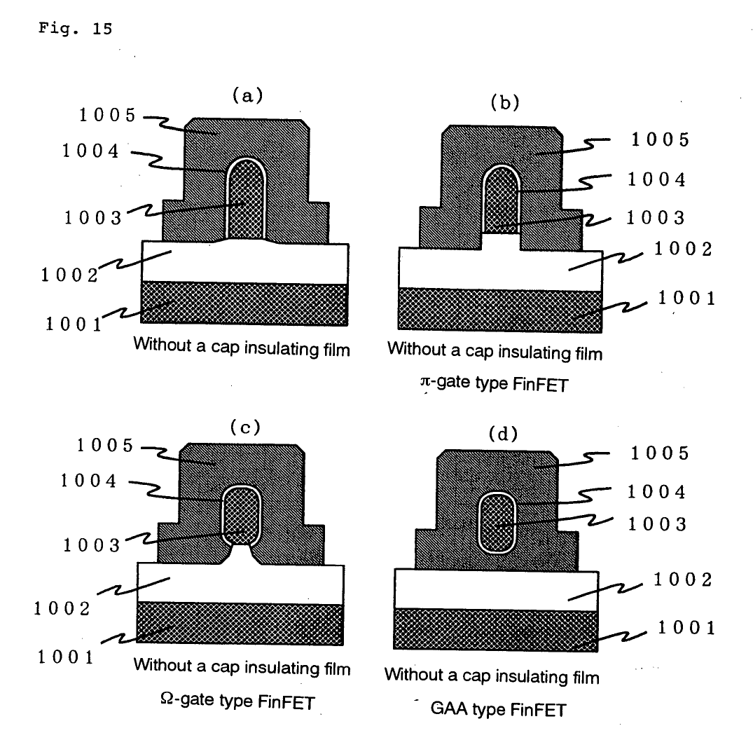

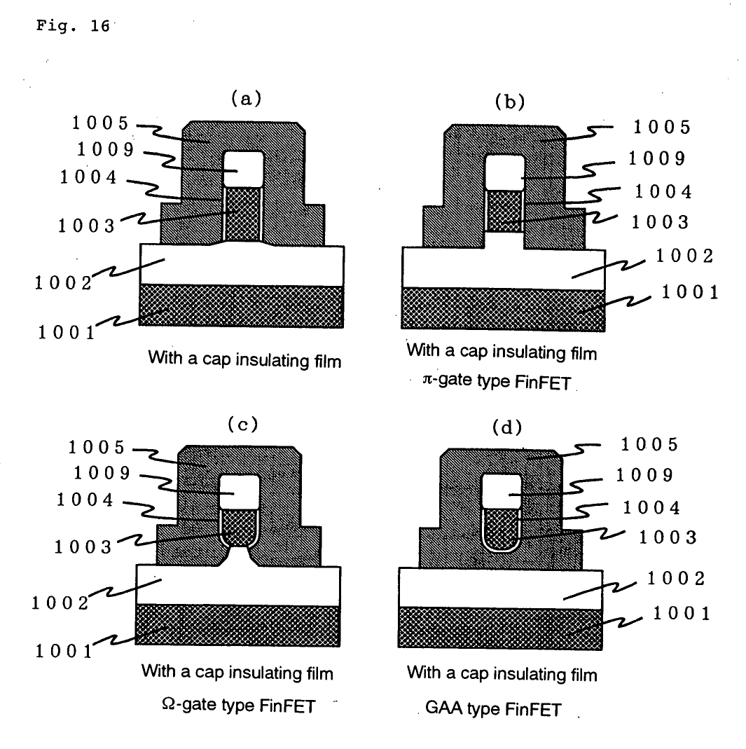

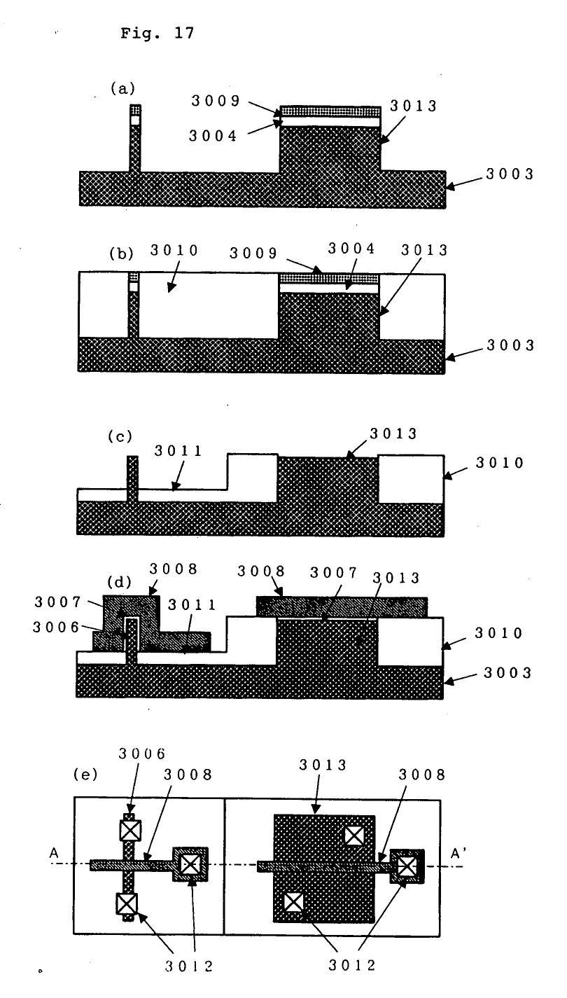

In a semiconductor device of this invention, a main channel is formed in the side surface of the protruding semiconductor region. In the upper plane (a plane parallel to the substrate) in the protruding semiconductor region, a channel may or may not be formed. FIG. 15 shows an exemplary cross-section of a protruding semiconductor region whose upper surface has a channel, and FIG. 16 shows an exemplary cross-section of a protruding semiconductor region whose upper surface has no channels. Whether a channel is formed on the upper surface of the protruding semiconductor region as described above can be selected by the presence or the absence of an insulating film with a larger thickness than a gate insulating film on the upper surface of the protruding semiconductor region. Furthermore, in the semiconductor device of this invention, the corner of the protruding semiconductor region can be rounded as in the semiconductor device in FIG. 15, to avoid electric field concentration.

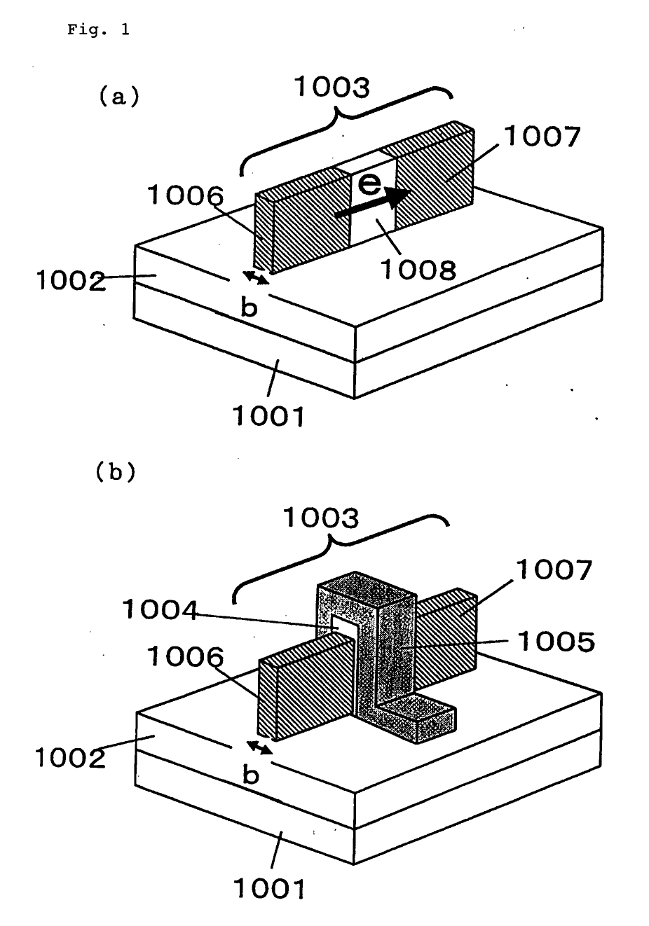

FIGS. 15(b) to (d) and 16(b) to (d) show an exemplary fin-type MISFET in which a gate electrode has a different structure from that described above. FIGS. 15 and 16 correspond to the cross-sectional view of FIG. 1(b). FIGS. 15(b) and 16(b) show a structure in which the lower end of the gate electrode 1005 is lower than the lower end of the semiconductor region 1003. This structure is called a “π-gate structure” because it resembles a Greek letter “π”. When a gate electrode extends to a lower position than the protruding semiconductor region as described above, control of a channel by the gate electrode can be reinforced, and sharpness of ON-OFF transfer (subthreshold property) can be improved, resulting in prevention of an OFF current.

FIGS. 15(c) and 16(c) show a structure in which a part of a gate electrode 1005 goes around to the undersurface of a semiconductor region 1003 (a structure where a gate electrode extends such that it covers a part of the lower surface of a protruding semiconductor region). This structure is called a “Ωgate structure” because it resembles a Greek letter “Ω”. Using this structure, control of a channel by the gate electrode can be further reinforced, and the undersurface of the semiconductor region can be utilized as a channel, resulting in improvement of driving ability.

FIGS. 15(d) and 16(d) show a structure where a gate electrode 1005 completely goes around to the undersurface of the semiconductor region 1003. This structure is called as a “gate-all-around (GAA) structure” because in the lower part of the gate electrode, the semiconductor region floats in the air in relation to the substrate plane. Using this structure, the undersurface of the semiconductor region can be also used as a channel, so that driving ability can be improved and short channel properties can be also improved.

A semiconductor material for forming a semiconductor region may be suitably monocrystal silicon. Other examples of a suitable material may include silicon-germanium and germanium. Alternatively, if necessary, a multilayer film of the above materials can be used.

Although a typical material under the base insulating film is silicon in the above embodiments, this invention can be constituted when there is an insulating film below the semiconductor region except that a fine structure in the semiconductor substrate under a base insulating film constitutes a semiconductor region. For example, like an SOS (silicon on sapphire, silicon on spinel), a structure in which an insulating material under a semiconductor region itself is a supporting substrate may be used. Examples of an insulating supporting substrate include, in addition to the above SOS, quartz and an AIN substrate. A semiconductor region can be formed on such a supporting substrate by a manufacturing process for an SOI (the steps of bonding and film-thinning).

A material for a gate electrode may be a conductive material having a desired conductivity and a desired work function. Examples include doped semiconductors such as doped polycrystal silicon, polycrystal SiGe, polycrystal Ge and polycrystal SiC; metals such as Mo, W, Ta, Ti, Hf, Re and Ru; metal nitrides such as TiN, TaN, HfN and WN; and silicides such as cobalt silicide, nickel silicide, platinum silicide and erbium silicide. Examples of a gate electrode structure may include, in addition to a single layer film, lamination structures such as a laminated film of a semiconductor and a metal film, a laminated film of metal films, and a laminated film of a semiconductor and a silicide film.

A gate insulating film may be, besides a SiO₂ film and a SiON film, a so-called high-dielectric-constant insulating film (High-K film). Examples of a High-K film include metal oxides such as a Ta₂O₅ film, an Al₂O₃ film, a La₂O₃ film, an HfO₂ film and a ZrO₂ film; and complex metal oxides represented by a composition formula such as HfSiO, ZrSiO, HfAlO and ZrAlO. A gate insulating film may have a laminated structure. An example is a laminated film formed by forming, on a semiconductor layer such as silicon, a silicon-containing oxide film such as SiO₂ and HfSiO, on which is then formed an High-K film.

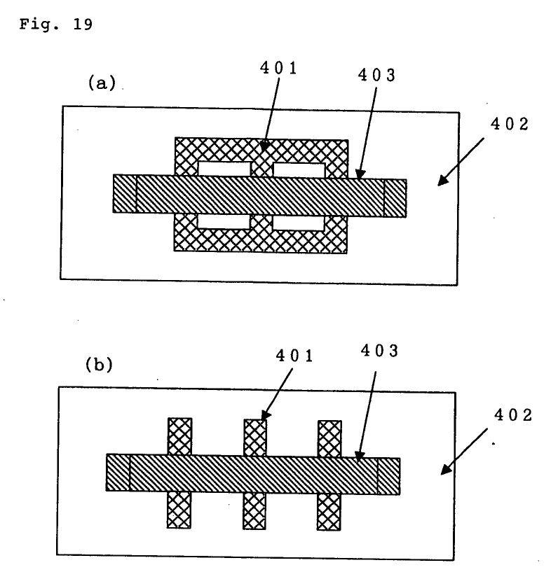

This invention relates to selection of a crystal orientation of a protruding semiconductor region. Herein, a crystal orientation of a semiconductor region constituting a Fin is expressed as an orientation of a Fin located in a crystal coordinate system. It may be interpreted to mean that a Fin is cut from a crystal in such a direction. For example, the state where a plane parallel to a substrate in a Fin is (001) and a surface parallel to a channel in the Fin is (110) corresponds to, as shown in FIG. 18(a), the state where a Fin is located in a crystal coordinate system such that the normal line of a plane parallel to a substrate has a <001> orientation and the normal line of a plane parallel to a channel has a <110> orientation (the hatched surface is in parallel with the substrate). The term “rotating” does not refer to actual rotation in a real space, but refers to change a crystal orientation of Fin based on the above expression, by rotating the Fin in a crystal coordinate system. For example, rotating the state of FIG. 18(a) by 45° centering around a <001> axis clockwise, that is, transfer of the state of FIG. 18(a) to the state of FIG. 18(b), means that a surface parallel to the channel is changed into a (010) plane without changing a plane parallel to the substrate from (001).

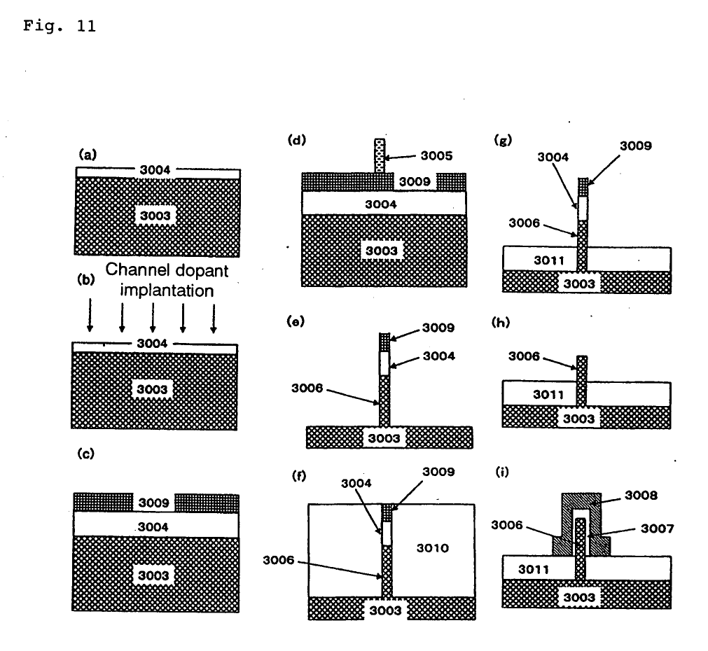

As shown in FIG. 10(f), a cross-sectional shape of a protruding semiconductor region including a gate electrode generally has two parallel lateral side surfaces which can have gate electrodes in both sides, and is typically square. In terms of relationship between a width and a height, generally height (H)/width (W) is within a range of ½ to 10, for example, 1 to 2. Typically, the upper surface of the protrusion is a plane parallel to the substrate. In the source region/drain regions other than the channel region, a width may be larger for, for example, forming a contact. A channel may be further formed on the upper surface of the protrusion. Here, the channels are formed in three surfaces, that is, the side surfaces and the upper surface of the protrusion, so that controllability by the gate electrode can be improved.

There will be described an example of a protruding semiconductor region in an MISFET having one independent channel region with reference to FIG. 1. FIG. 1(a) is a perspective view illustrating a protruding semiconductor region formed on an insulator, and FIG. 1(b) is a perspective view illustrating an MISFET. As shown in FIG. 1(a), on a semiconductor substrate 1001 is formed an insulator 1002 made of SiO₂, on which is then formed a protruding semiconductor region 1003. The semiconductor region 1003 has a channel region (the side surface of the protrusion) 1008. In FIG. 1, the semiconductor region is a rectangular solid.

In this semiconductor region 1003, a channel region and source/drain regions are formed. As shown in FIG. 1(b), a gate insulating film 1004 is formed on the upper surface and the side surfaces of the semiconductor region 1003, and a gate electrode 1005 is formed, striding over the semiconductor region 1003 having the gate insulating film 1004 on its surface. An appropriate gate voltage is applied to the gate electrode 1005 to form a main channel region 1008 in a part of the protruding semiconductor region 1003. The side parts sandwiching the gate electrode 1005 of the semiconductor region 1003 constitutes a source region 1006 a drain region 1007 which are doped with a dopant in a high concentration.

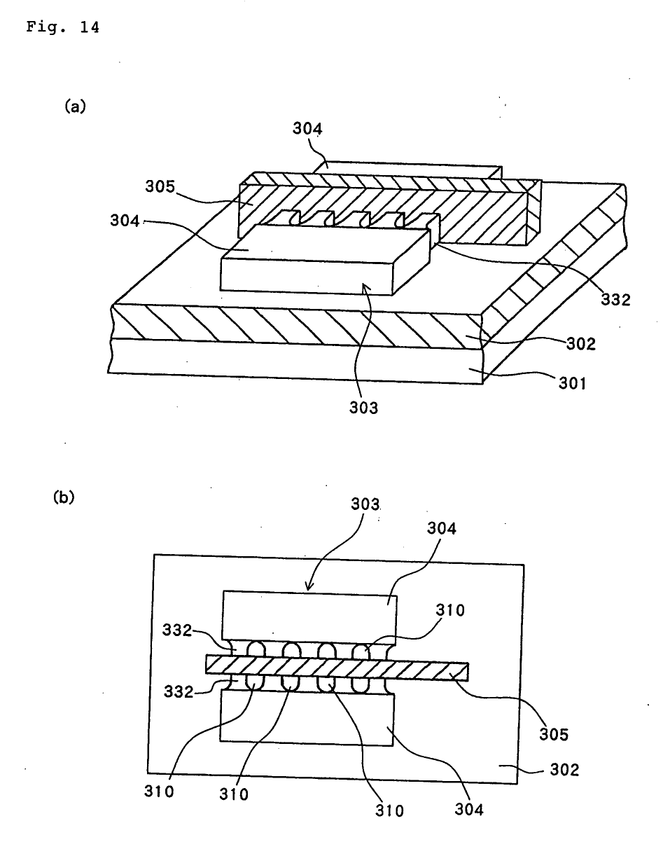

An MISFET may have a multi-structure having a plurality of channel regions as shown in FIGS. 13 and 14. In the MISFET having the structure shown in FIG. 13, there are formed a semiconductor layer 213, a channel 215 and source/drain regions 217, which protrude from the insulating film 214. In this structure, a gate electrode is shared by the plurality of channels, and the source/drain regions are mutually connected by interconnects. In the MISFET shown in FIG. 14, a channel region and source/drain regions (304, 332) are formed in a semiconductor layer 303 protruding from an insulating film 302. The source/drain regions 304 are regions shared by a plurality of channel regions. In either structure in FIG. 13 or 14, the channel regions are connected in parallel, and thus acts as one MISFET as a whole. FIG. 19 is a plan view schematically illustrating a multi-structure MISFET. In the MISFET shown in FIG. 19(a), a pair of source/drain regions 401 are formed, which is shared by each semiconductor layer. In the MISFET shown in FIG. 19(b), a pair of source/drain regions 401 is independently formed for each semiconductor layer. Having such a multi-structure, a fin-type MISFET can have a larger channel width in a smaller area, so that driving ability can be more effectively improved when changing a crystal orientation of the side surface of a protrusion as in this invention.

The fin-type MISFET of this invention has the same structure as that in a conventional fin-type MISFET in that a protruding semiconductor region is formed on a substrate and a channel is formed in the side surface of the semiconductor region, but different from a conventional fin-type MISFET in that a crystal orientation is different in a protruding semiconductor region and carrier mobility properties are improved.

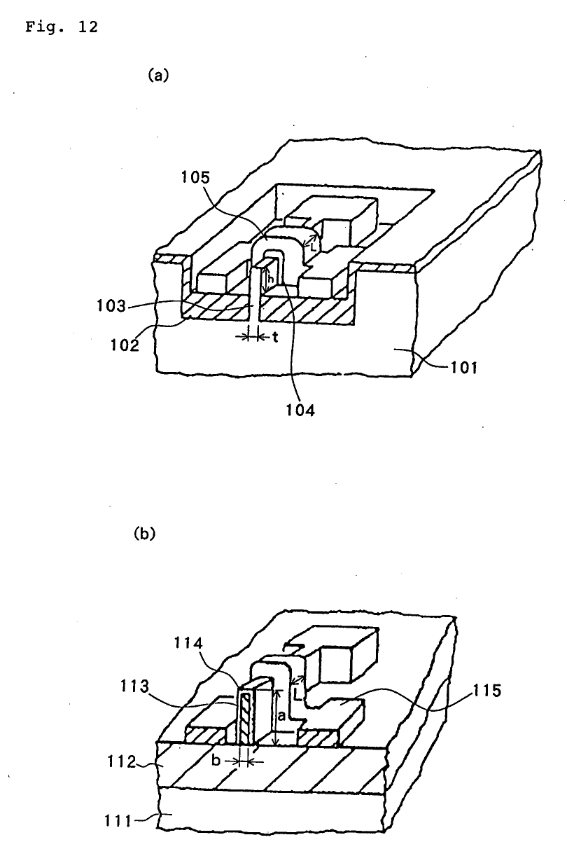

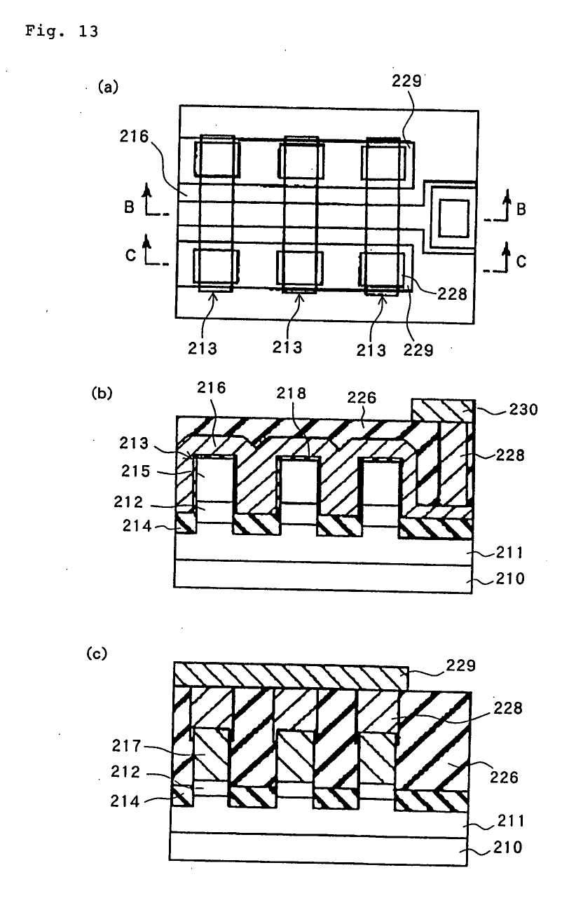

The semiconductor region may be a part of a semiconductor substrate 1001 as shown in FIG. 12(a) or a silicon monocrystal layer in an SOI substrate as shown in FIG. 12(b). In either case, it protrudes from an insulating layer (an insulating film 102 in FIG. 12(a), and an insulating film 112 in FIG. 12(b)) intervening between the substrate and the region where a device is formed, so that it can have a side where a channel can be formed. In terms of the semiconductor region, the two types of the fine structure of the semiconductor substrate 1001 and a silicon monocrystal layer in the SOI substrate may coexist on the same substrate.

In the fin-type MISFET of this invention, a crystal orientation of the protruding semiconductor region 1003 affects carrier mobility while a crystal orientation of the substrate 1001 does not affect carrier mobility. Therefore, a crystal orientation of the protruding semiconductor region 1003 does not have to be identical to a crystal orientation of the substrate 1001. For example, when using an SOI substrate prepared by bonding, a plane parallel to the substrate in a semiconductor region may have a crystal orientation different from that of the substrate. As used herein, the term “surface parallel to a substrate” or “plane parallel to a substrate” refer to a crystal orientation of the protruding semiconductor region 1003, more strictly a semiconductor crystal constituting the channel region 1008, but not to a crystal orientation of the substrate 1001.

When, as a desirable forming process, forming a plurality of protruding semiconductor regions as a part of a semiconductor monocrystal substrate or as a processed silicon monocrystal layer in an SOI substrate, the protruding semiconductor regions have an identical crystal orientation. When constituting a CMIS using such a protruding semiconductor region, a p-type and a n-type MISFETs are formed as protruding crystals with an identical orientation. Therefore, in the p-type and the n-type MISFETs, a crystal orientation of a plane parallel to each substrate is the same plane.

A full depletion type MISFET can be obtained by reducing a width of a semiconductor region (it represents a length in the direction parallel to the substrate in the protruding semiconductor region; “b” in FIGS. 1 and 12(b), and “t” in FIG. 12(a)) such that when the fin-type MISFET is ON, the whole protruding region where a channel is formed is depleted. The fin-type MISFET may or may not be of a full depletion type. The semiconductor region may or may not be appropriately doped with a dopant.

A semiconductor device of this invention typically has the almost same number of n-type and p-type field effect transistors pairwise, which are used as CMIS circuits. Alternatively, they may be used in a circuit where one conduction type (for example, n-type) field effect transistor is main while the other conduction type (for example, p-type) field effect transistor is auxiliary. Furthermore, this invention may include a CMIS or other circuit having the relationship between crystal orientations as described above at least in a part of a semiconductor device (chip).

A semiconductor device of this invention may have two or more CMISs. In the semiconductor device of this invention, MISFETs can be arranged in orthogonal and/or parallel, so that layout is easy and a number of MISFETs can be placed in a smaller area, allowing a semiconductor device to be more integrated.

### EMBODIMENT 1

In Embodiment 1 of this invention, planes parallel to a substrate in an n-type and a p-type MISFETs is a (100) plane (including a surface having an off angle of 10° or less). When a state where a crystal orientation of the side surfaces of the protrusions in the n-type and the p-type MISFETs is a (110) plane perpendicular to the substrate is a reference state, the n-type and the p-type MISFETs of this invention correspond to those obtained by independently fixing or rotating the side surface of the protrusion of the MISFET in the reference state centering around the normal line of the substrate by an angle of 0° to 90° both inclusive (except the case where both of the rotation angles of the n-type and the p-type MISFETs are 0° or 90°) while fixing the plane parallel to the substrate. As used herein, the term “rotating the side surface of a protrusion” does not mean actual rotation in a real space, but means that a Fin is rotated within a crystal coordinate system while fixing a crystal orientation of a plane parallel to the substrate in the MISFET, to change a crystal orientation of the Fin in the crystal coordinate system. It means that a protruding semiconductor region is formed such that it has a side surface to be a current direction. The side surface of the protrusion can be fixed or rotated as described above, to optimize a delay index in a CMIS and arrangement of MISFETs taking a layout into consideration.

The mobility data used in this invention were determined using a commercially available semiconductor parameter analyzer. The measurement conditions were a drain voltage: 0.05 V and a substrate voltage: 0 V, in reference to a source voltage. A gate voltage was adjusted for each sample such that a vertical effective electric field Eeff applied to a channel is 10 MV/cm, and was about 1.35 V. When a common polysilicon gate electrode was used, it is approximately obtained from the following equation:
Eeff=(Vgs+Vth)/6Tox

wherein Vgs: gate voltage, Vth: threshold voltage, and Tox: thickness of a gate oxide film.

A delay index is an indicator for evaluating carrier mobility properties of a CMIS and was calculated from the following equation:

A delay index is expressed as a number without a unit calculated by normalizing all mobility determined as described above into a mobility of an n-type MISFET (240 cm²/V·s) in which the side surface of a protruding semiconductor region is a {100} plane. The lower a delay index is, the better carrier mobility properties in a CMIS are. The plane parallel to the substrate in the MISFET may be any of a (100) plane, a (010) plane and a (001) plane. With any of these planes as the plane parallel to the substrate, comparable mobility can be obtained because of symmetry of a silicon crystal when the side surface of the protrusion of the MISFET is perpendicular to the substrate and the side surfaces of the protrusions in the n-type and the p-type MISFETs are rotated by an equal angle.

For example, when a crystal orientation of a plane parallel to a substrate in an MISFET is a (100) plane, a reference state is an arrangement that a crystal orientation of the side surfaces of the protrusions in the n-type and the p-type MISFETs is a (0-11) plane and/or a (011) plane, and the side surface of the protrusion in the MISFET is rotated centering around <100>. When a crystal orientation of a plane parallel to the substrate in the MISFET is a (010) plane, a reference state is an arrangement that a crystal orientation of the side surfaces of the protrusions in the n-type and the p-type MISFETs is a (10-1) plane and/or a (101) plane, and the side surface of the protrusion in the MISFET is rotated centering around <010>. When a crystal orientation of a plane parallel to the substrate in the MISFET is a (001) plane, a reference state is an arrangement that a crystal orientation of the side surfaces of the protrusions in the n-type and the p-type MISFETs is a (−110) plane and/or a (110) plane, and the side surface of the protrusion in the MISFET is rotated centering around <001>. Here, a plane direction of the plane parallel to the substrate in the MISFET is unchanged by the rotation of the side surface of the protrusion. These reference states correspond to a fin-type MISFET in a conventional semiconductor device.

For the side surface of the protrusion in the MISFET, the normal line of the substrate is a four-fold axis. Thus, when a rotation angle of the side surface of the protrusion in the MISFET is 90°, mobility is equal to that in the reference state, and when further increasing a rotation angle from 90°, mobility behaves as in the case where a rotation angle is increased from 0° to 90°. Therefore, a rotation angle of the side surface of the protrusion in the MISFET from 0° to 90° can represent movement at the whole rotation angle (0 to 360°).

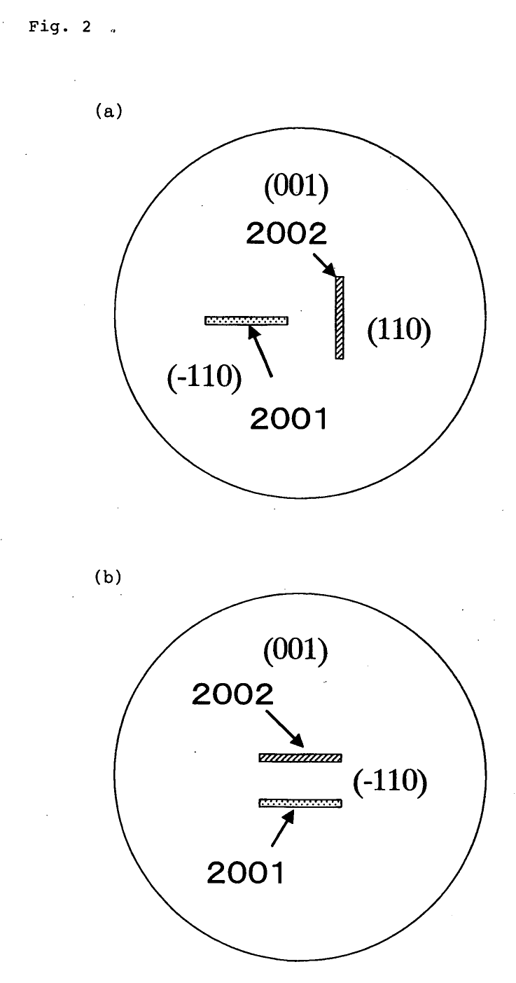

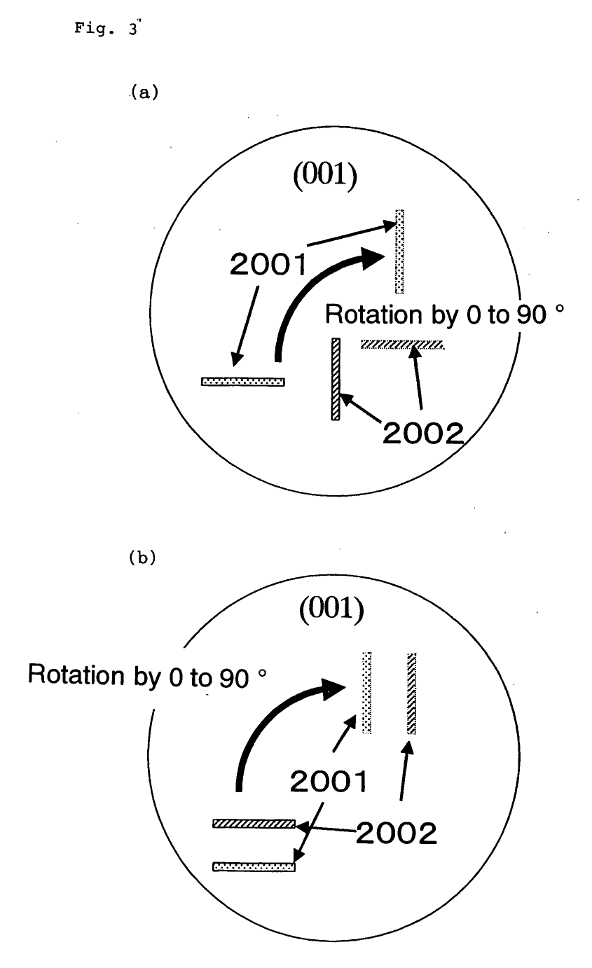

FIGS. 2(a) and 2(b) show reference states where a crystal orientation of a plane parallel to the substrate is a (001) plane and the n-type and the p-type MISFETs are positioned in orthogonal or parallel, respectively. FIGS. 2(a) and (b) are the figures when these MISFETs are looked from <00-1>. In Embodiment 1 of this invention, the side surfaces of the protrusions in the n-type MISFET 2001 and the p-type MISFET 2002 are independently fixed or rotated centering around <001> by an angle of 0° to 90° both inclusive, from the reference states of FIGS. 2(a) and (b) to those of FIGS. 3(a) and (b).

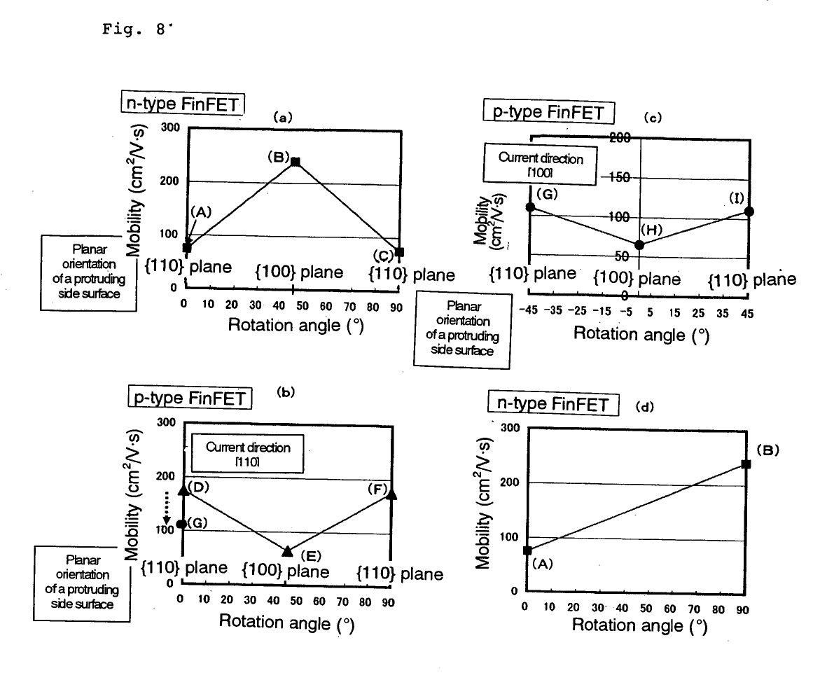

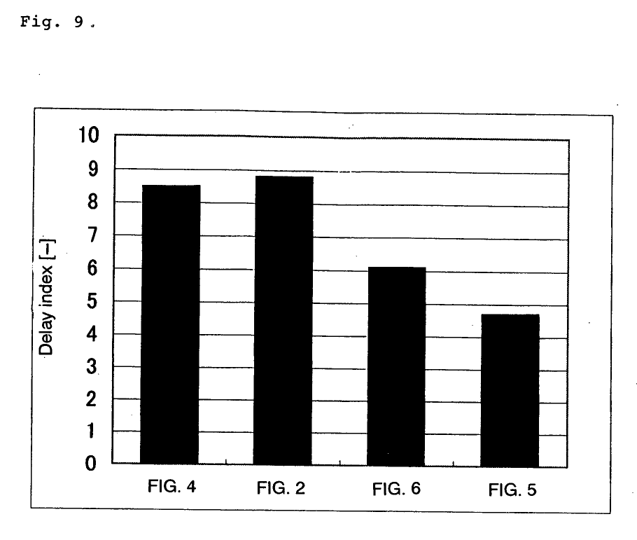

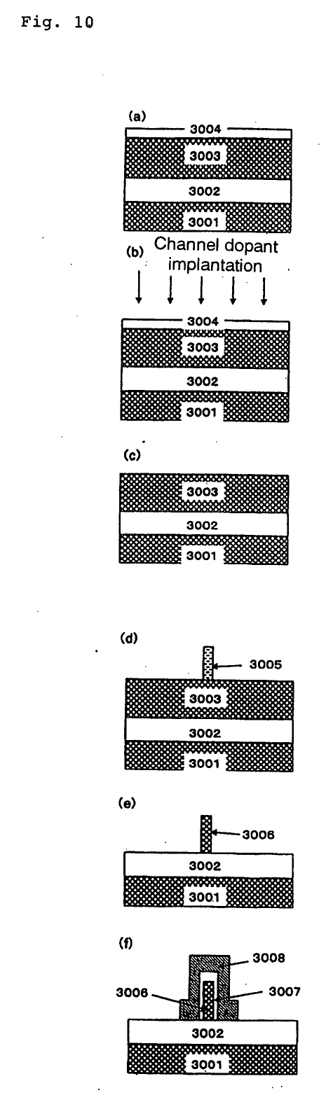

There will be described variation in carrier mobility properties when rotating the side surfaces of the protrusions as described above, with reference to FIGS. 8 and 9. FIG. 8(a) shows relationship between carrier mobility in an n-type MISFET and a crystal orientation; FIG. 8(b) shows relationship between carrier mobility in a p-type MISFET and a crystal orientation; and FIG. 9 shows relationship between a delay index in a CMIS and a crystal orientation.

A mobility of an arrangement in FIGS. 2(a) and (b) (conventional CMIS) is indicated by point (A) in FIG. 8(a) and point D in FIG. 8(b), respectively. Here, a delay index of the CMIS determined is 8.8 from FIG. 9. In contrast, when rotating the sides of the protrusions in the n-type and the p-type MISFETs to 90° as in FIGS. 3(a) and (b), a mobility in the n-type MISFET monotonically increases from point (A) to point (B) in FIG. 8(a), and then reaches point (C). On the other hand, a mobility in the p-type MISFET monotonically decreases from point (D) to point (E) in FIG. 8(b), and then reaches point (F). Points (A) and (D) represent a mobility in the reference state, and points (C) and (F) represent a mobility when a rotation angle of the side surface of the protrusion is 90°. From symmetry in a crystal, a mobility in point (A) is substantially the same as in point (C) and a mobility in point (D) is substantially the same as in point (F).

A rotation angle may be equal or different between the side surfaces of the protrusions in the n-type and the p-type MISFETs. Alternatively, only the side surface of the protrusion in either of the n-type or the p-type MISFETs may be rotated, while the side surface of the protrusion in the other may be fixed, provided that it does not include the case that both of the side surfaces of the protrusions in the n-type and the p-type MISFETs are fixed to the reference state or rotated by 90° from the reference state because a mobility is identical to that in a conventional MISFET corresponding to the arrangement in FIGS. 2(a) and (b) due to symmetry in a silicon crystal.

Furthermore, from FIG. 8, when rotating only the side surface of the protrusion in the p-type MISFET while fixing the side surface of the protrusion in the n-type MISFET, a mobility in the p-type MISFET is reduced, compared to the reference state. Therefore, from FIG. 9, a delay index of the CMIS determined is increased, leading to deterioration in carrier mobility properties. Thus, when rotating the side surface of the protrusion in the p-type MISFET, the side surface of the protrusion in the n-type MISFET should be also rotated for preventing a delay index in the CMIS from being larger than that in the reference state. Preferably, while maintaining the arrangement that the side surfaces of the protrusions in the n-type and the p-type MISFETs are positioned in orthogonal or parallel, the side surfaces of the protrusions in these MISFETs are rotated by an equal angle. By rotating them by an equal angle as described above, layout of these MISFETs can be facilitated and a delay index in the CMIS can be reduced.

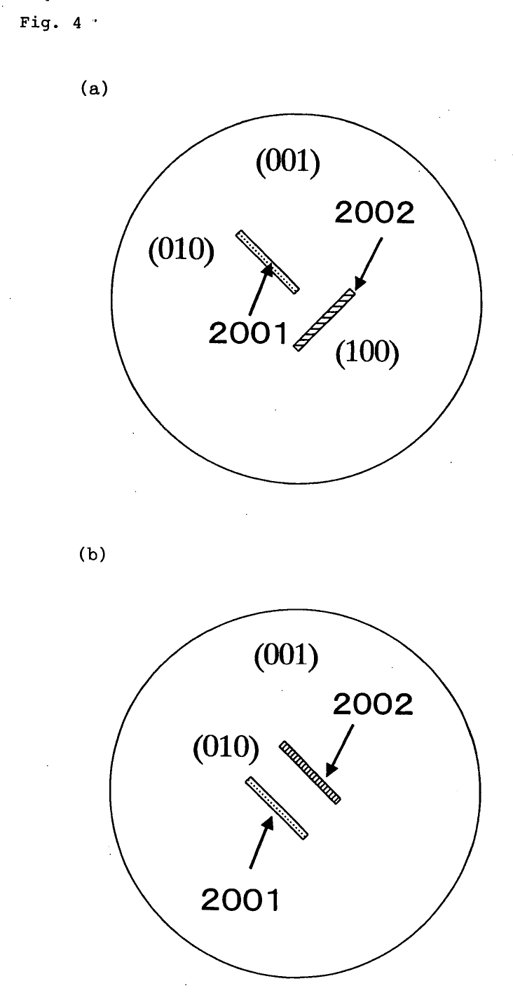

In one preferred aspect, both of the side surfaces of the protrusions in the n-type and the p-type MISFETs are rotated by an angle of 45°. FIGS. 4(a) and (b) show a semiconductor device in the reference state in FIGS. 2(a) and (b), from <00-1>. In FIG. 4(a), a crystal orientation of the side surface of the protrusion in the n-type MISFET 2001 is a (010) plane and a crystal orientation of the side surface of the protrusion in the p-type MISFET 2002 is a (100) plane. In FIG. 4(b), a crystal orientation is a (010) plane in both of the side surfaces of the protrusions in the n-type MISFET 2001 and the p-type MISFET 2002. Mobilities in the n-type and the p-type MISFETs are represented by point (B) in FIG. 8(a) and point (E) in FIG. 8(b).

From FIG. 8(a), in the state of point (B), a mobility in the n-type MISFET is higher than that in the reference state (point (A)), and from FIG. 9, a delay index of the CMIS determined is reduced from 8.8 (reference state) to 8.5. Therefore, carrier mobility properties in the CMIS is improved in comparison with a conventional CMIS. Furthermore, since the side surfaces of the protrusions in the n-type and the p-type MISFETs mutually are positioned in orthogonal or parallel, layout of the MISFET may be facilitated and an arrangement of the MISFETs can be optimized.

From FIG. 8(b), when fixing or rotating the side surface of the protrusion in the p-type MISFET by an angle of 0° to 10° both inclusive from the reference state, a mobility in the p-type MISFET is fixed at point (D) in FIG. 8(b) or is near point (D), indicating a higher mobility. When the side surface of the protrusion in the n-type MISFET is rotated by an angle of 90° or less while handling the side surface of the protrusion in the p-type MISFET as described above, a mobility moves from point (A) in FIG. 8(a), through point (B), to point (C). Thus, a mobility in the n-type MISFET can be increased in comparison with the reference state. Furthermore, a delay index in the CMIS can be reduced in comparison with the reference state and carrier mobility properties in the CMIS can be improved in comparison with a conventional CMIS.

In another preferred embodiment, the side surfaces of the protrusions in the n-type and the p-type MISFETs are rotated by an angle such that mobilities in the n-type and the p-type MISFETs are within a preferable range. Preferably, the side surface of the protrusion in the p-type MISFET is fixed or rotated by an angle of 0° to 10° both inclusive from the reference state and the side surface of the protrusion in the n-type MISFET is rotated by 45°.

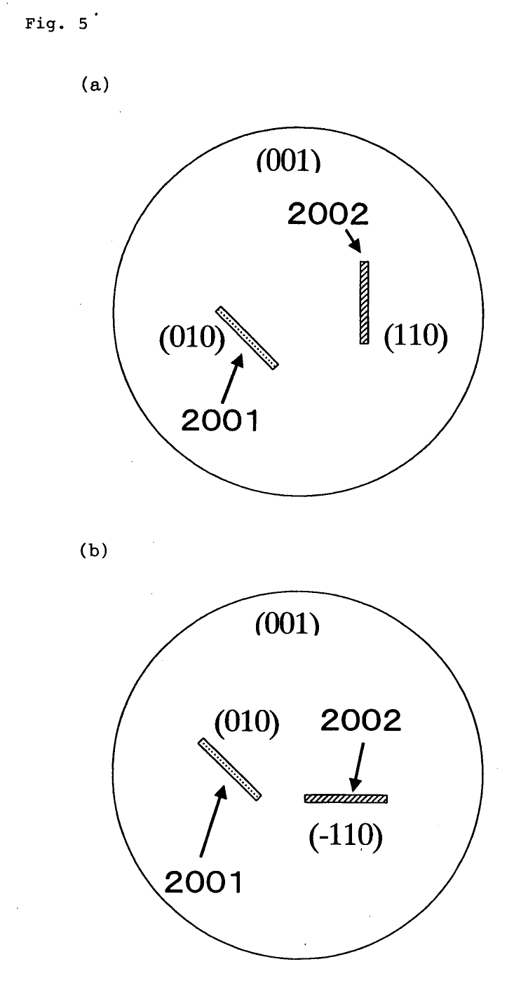

FIGS. 5(a) and (b) show a semiconductor device in the reference state shown in FIGS. 2(a) and (b) from <00-1>(the side surface of the protrusion in the p-type MISFET is fixed to the reference state). In FIG. 5(a), a crystal orientation of the side surface of the protrusion in the n-type MISFET 2001 is a (010) plane and a crystal orientation of the side surface of the protrusion in the p-type MISFET 2002 is a (110) plane. In FIG. 5(b), a crystal orientation of the side surface of the protrusion in the n-type MISFET 2001 is a (010) plane and a crystal orientation of the side surface of the protrusion in the p-type MISFET 2002 is a (−110) plane. Here, a mobility in the n-type MISFET is represented by point (B) in FIG. 8(a) and a mobility in the p-type MISFET is represented by point (D) in FIG. 8(b).

From FIG. 8, in comparison with the reference state (point (A)), a mobility in the n-type MISFET is increased and a mobility in the p-type MISFET is equal to that at point (D). Therefore, from FIG. 9, a delay index of the CMIS determined is reduced from 8.8 (the reference state) to 4.7, and carrier mobility properties in the CMIS are improved in comparison with a conventional CMIS.

The arrangements in FIGS. 5(a) and (b) can be obtained by rotating the side surface of the protrusion once or multiple times from the arrangements in FIGS. 2(a) and (b). For example, only the side surface of the protrusion in the n-type MISFET in the arrangements in FIGS. 2(a) and (b) can be rotated by 45° to obtain the arrangements in FIGS. 5(a) and (b). Here, a mobility in the n-type MISFET moves from point (A) through FIG. 8(a) to point (B). On the other hand, a mobility in the p-type MISFET does not move from point (D) in FIG. 8(b). Thus, the side surface of the protrusion can be rotated to provide a CMIS having excellent carrier mobility properties.

Alternatively, after the arrangements in FIGS. 2(a) and (b) are changed into the arrangements in FIGS. 4(a) and (b) by rotating the side surface of the protrusion, the side surface of the protrusion in the p-type MISFET can be further rotated by 45° to provide the arrangements in FIGS. 5(a) and (b). Here, a mobility in the n-type MISFET moves from point (A) to point (B) on FIG. 8(a). On the other hand, for example, for obtaining the state in FIG. 5(b), a mobility in the p-type MISFET moves from point (D) to point (E) on FIG. 8(b) (rotation of the side surface of the protrusion from FIG. 2 to FIG. 4) and then reaches point (F) when FIG. 2(a) is the reference state and returns to point (D) when FIG. 2(b) is the reference state (rotation of the side surface of the protrusion from FIG. 4 to FIG. 5). By rotating the side surface of the protrusion as described above, a CMIS having excellent carrier mobility properties can be obtained.

In this embodiment, a crystal orientation of the planes parallel to the substrate in the n-type and the p-type MISFETs is a {100} plane. Preferably, a crystal orientation of the side surface of the protruding semiconductor region in the n-type MISFET is a {100} plane substantially orthogonal to the plane parallel to the substrate. Here, from FIG. 8(a), the n-type MISFET has the maximum mobility. Thus, with any of these crystal orientations of the side surface of the protruding semiconductor region in the p-type MISFET, a delay index in a CMIS is reduced in comparison with the case where a crystal orientation is substantially a {110} plane in the side surface of the protruding semiconductor region in both n-type and p-type MISFETs. Thus, a CMIS having excellent carrier mobility properties can be obtained.

Preferably, a crystal orientation of the side surface of the protruding semiconductor region in the p-type MISFET is a {110} plane substantially orthogonal to a plane parallel to the substrate, and a crystal orientation of the protruding semiconductor region in the n-type MISFET is different from the {110} plane. Here, from FIG. 8(b), a mobility in the p-type MISFET is maximum. From FIG. 8(a), a mobility in the n-type MISFET is not minimum (points (A) and (C) in FIG. 8(a)). Therefore, in comparison with the case where a crystal orientation is substantially a {110} plane for the side surfaces of the protruding semiconductor regions in both n-type and p-type MISFETs, a delay index in the CMIS is reduced. Thus, a CMIS having excellent carrier mobility properties can be obtained.

More preferably, a crystal orientation of the side surface of the protruding semiconductor region in the n-type MISFET is substantially a {100} plane orthogonal to the plane parallel to the substrate, and a crystal orientation of the side surface of the protruding semiconductor region in the p-type MISFET is substantially a {110} plane orthogonal to the plane parallel to the substrate. Here, from FIGS. 8(a) and (b), mobilities in the n-type and the p-type MISFETs are maximum, so that a delay index in the CMIS is low, resulting in a CMIS having excellent carrier mobility properties.

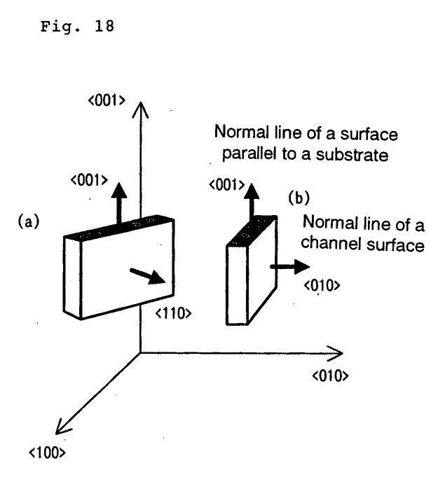

Since the plane parallel to the substrate is {100}, Embodiment 1 is advantageous when a fin-type transistor and a planar type transistor are on the same substrate firstly because mobilities in a CMIS consisting of a planar type transistor and of an n-type MISFET are most advantageous when they are formed in a {100} plane and secondly because in terms of a design, a MISFET on a {100} plane is interchangeable with a conventional planar MISFET. FIG. 17 shows an exemplary structure having a fin-type transistor and a planar type transistor in combination.

### EMBODIMENT 2

In Embodiment 2 of this invention, a reference state is the state where a crystal orientation of planes parallel to the substrate of an n-type and a p-type MISFETs (including a surface with an off angle of 10° or less), a crystal orientation of the side surface of a protrusion in the n-type MISFET and a crystal orientation of the side surface of a protrusion in the p-type MISFET are mutually orthogonal {100} planes. It corresponds to the state obtained by fixing or rotating planes parallel to the substrate of the n-type and the p-type MISFETs and the side surface of the protrusion in the p-type MISFET by an angle of −45° to 45° both inclusive centering around the normal line of the side surface of the protrusion in the n-type MISFET. As used herein, the term “rotating” does not refer to actual rotation in a real space, but refers to changing a crystal orientation of a Fin by rotating the Fin within a crystal coordinate system while fixing a relative crystal orientation arrangement of the n-type and the p-type MISFETs. That is, it means that a protruding semiconductor region is formed such that it has a side surface exhibiting such a current direction.

Having such a crystal orientation, a CMIS can have improved carrier mobility properties. Since the n-type and the p-type MISFETs are disposed such that the side surfaces of the protrusions are mutually orthogonal, an optimal arrangement in which the MISFETs can be easily laid out can be designed.

A plane parallel to the substrate in the MISFET in the reference state may be any of a (100) plane, a (010) plane and a (001) plane. For any of these planes as the plane parallel to the substrate, a crystal orientation of the planes parallel to the substrate of the n-type and the p-type MISFETs (including a surface having an off angle of 10° or less) and a crystal orientation of the side surface of the protrusion are mutually orthogonal {100} planes, which are equivalent because of symmetry of a crystal.

For example, <001> is a center of rotation in the reference state where a crystal orientation of the plane parallel to the substrate in the MISFET is a (100) plane, a crystal orientation of the side surface of the protrusion in the n-type MISFET is a (001) plane and a crystal orientation of the side surface of the protrusion in the p-type MISFET is a (010) plane. Furthermore, <100> is a center of rotation in the reference state where a crystal orientation of the plane parallel to the substrate in the MISFET is a (010) plane, a crystal orientation of the side surface of the protrusion in the n-type MISFET is a (100) plane and a crystal orientation of the side surface of the protrusion in the p-type MISFET is a (001) plane. Furthermore, <010> is a center of rotation in the reference state where a crystal orientation of the plane parallel to the substrate in the MISFET is a (001) plane, a crystal orientation of the side surface of the protrusion in the n-type MISFET is a (010) plane and a crystal orientation of the side surface of the protrusion in the p-type MISFET is a (100) plane.

The normal line of the side surface of the protrusion in the n-type MISFET is a four-fold axis for the side surface of the protrusion in the p-type MISFET. Thus, when a rotation angle of the side surface of the protrusion in the p-type MISFET is 45°, a mobility in the p-type MISFET is equal to that for −45°, and further increasing a rotation angle from 45° results in mobility behavior as is in increasing an angle from −45°. Therefore, in terms of a rotation angle of the side surface of the protrusion in the p-type MISFET, an angle of −45° to 45° both inclusive can represent a mobility in the whole rotation angle (−180 to 180°).

The rotation is conducted centering around the normal line of the side surface of the protrusion in the n-type MISFET. Therefore, as the rotation proceed, a crystal orientation of the side surface of the protrusion in the p-type MISFET and the plane parallel to the substrate in the MISFET is changed while a plane direction (direction of the normal line of a surface or plane) of the side surface of the protrusion in the n-type MISFET is unchanged.

Preferably, the side surface of the protrusion is fixed to the reference state. FIG. 4 shows the reference state where a crystal orientation of a plane parallel to the substrate in the MISFET is a (001) plane, a crystal orientation of the side surface of the protrusion in the n-type MISFET is a (010) plane and a crystal orientation of the side surface of the protrusion in the p-type MISFET is a (100) plane, from <00-1>. There will be described variation in carrier mobility properties when the side surface of the protrusion is rotated from the reference state. FIG. 8(c) shows relationship between a mobility in the p-type MISFET and a crystal orientation. In FIG. 8(b), the side surface of the protrusion in the p-type MISFET is rotated around the normal line of the substrate while in FIG. 8(c), the side surface of the protrusion is rotated around the normal line of the side surface of the protrusion in the n-type MISFET. Thus, the rotation axes of the side surfaces of the protrusions are different between FIGS. 8(b) and 8(c). In the reference state, a mobility in the n-type MISFET is represented by point (B) in FIG. 8(a) and a mobility in the p-type MISFET is represented by point (H) in FIG. 8(c). Here, a delay index in the CMIS determined is 8.5 from FIG. 9. The planes corresponding to point (E) in FIG. 8(b) and point (H) in FIG. 8(c) are equivalent.

In contrast, when the side surface of the protrusion is rotated by an angle within the range of −45° or more and less than 0° centering around the normal line of the side surface of the protrusion in the n-type MISFET, a plane direction of the side surface of the protrusion in the n-type MISFET is unchanged, so that a mobility does not move from point (B) in FIG. 8(a). On the other hand, a carrier mobility in the p-type MISFET reaches point (G) in FIG. 8(c).

Point (G) represents a mobility when the side surface of the protrusion is rotated by −45°, and point (H) represents a mobility in the p-type MISFET in the reference state. When rotating the side surface of the protrusion by an angle in the range of more than 0 and 45° or less, a carrier mobility in the p-type MISFET moves from point (H) in FIG. 8(c) to point (I). Point (I) represents a mobility in the p-type MISFET when the side surface of the protrusion is rotated by 45°. Because of symmetry of the crystal, the mobility at point (G) is identical to the mobility at point (I). Point (I) represents a mobility in the p-type MISFET when the side surface of the protrusion is rotated by 45°.

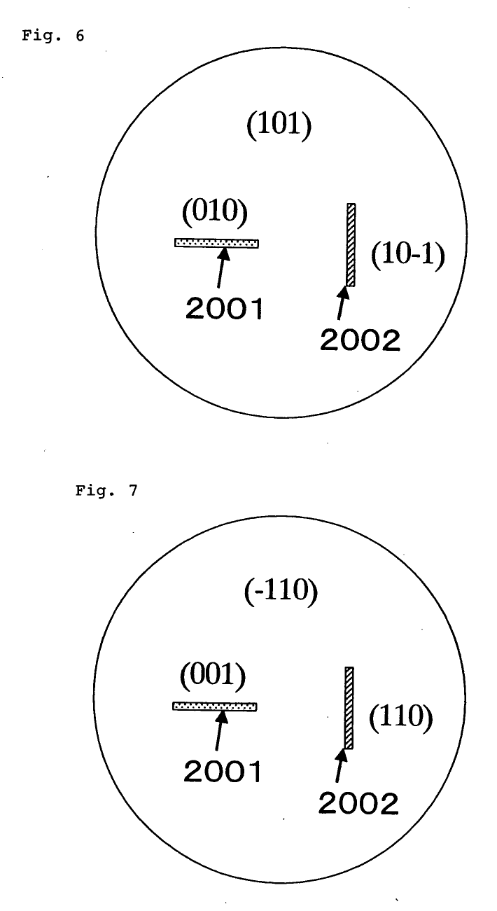

Preferably, the side surfaces of the protrusions in the n-type and the p-type MISFETs are rotated by 45°. FIG. 6 shows a semiconductor device after rotating the side surface of the protrusion by 45° when the arrangement in FIG. 4 is a reference state. FIG. 6 is a figure when the arrangement is looked from <101>. In this arrangement, a crystal orientation of the side surface of the protrusion in the n-type MISFET 2001 is a (010) plane, a crystal orientation of the side surface of the protrusion in the p-type MISFET 2002 is a (10-1) plane, a crystal orientation of the plane parallel to the substrate in the MISFET is a (101) plane. A mobility in the n-type MISFET is represented by point (B) in FIG. 8(a), and a mobility in the p-type MISFET is represented by point (I) in FIG. 8(c). From FIG. 9, a delay index in the CMIS determined is 6.1, which is lower than that in a conventional CMIS corresponding to the arrangement in FIG. 2. Therefore, the carrier mobility properties of the CMIS are improved in comparison with the conventional CMIS. When a rotation angle is −45°, equivalent results can be obtained.

Preferably, a crystal orientation of the side surface of the protruding semiconductor region in the n-type MISFET is substantially a {100} plane, and the side surfaces of the protruding semiconductor regions in the n-type and the p-type MISFETs are orthogonal. Here, both of crystal orientations of the plane parallel to the substrate in the MISFET and the side surface of the protrusion in the p-type MISFET can be a {100} plane or a {110} plane. Furthermore, from FIG. 8(a), a mobility in the n-type MISFET is maximum, so that a delay index in a CMIS can be reduced, resulting in a CMIS having excellent carrier mobility properties.

More preferably, crystal orientations of the protruding semiconductor regions in the n-type MISFET are substantially a {110} plane for the plane parallel to the substrate and substantially a {100} plane orthogonal to the {110} plane for its side surface, and crystal orientations of the protruding semiconductor region in the p-type MISFET are substantially a {110} plane for the plane parallel to the substrate and substantially a {110} plane orthogonal to the {110} plane for its side surface. Here, from FIGS. 8(a) and (c), mobilities in the n-type and the p-type MISFETs are maximum for this embodiment, so that a delay index in a CMIS can be reduced, resulting in a CMIS having excellent carrier mobility properties.

### EMBODIMENT 3

In Embodiment 3 of this invention, a reference state is a state where a crystal orientation of planes parallel to substrate in an n-type and a p-type MISFETs (including a surface with an off angle of 10° or less) is a {100} plane, a crystal orientation of the side surfaces of protrusions in an n-type and a p-type field effect transistors is a {110} plane, and these three planes are mutually orthogonal. It corresponds to the state after rotating the planes parallel to the substrate in the n-type and the p-type MISFETs and the side surface of the protrusion in the n-type MISFET by an angle of 90° or less centering around the normal line of the side surface of the protrusion in the p-type MISFET.

As used herein, the term “rotating” does not refer to actual rotation in a real space, but refers to changing a crystal orientation of a Fin by rotating the Fin within a crystal coordinate system while fixing a relative crystal orientation arrangement of the n-type and the p-type MISFETs. That is, it means that a protruding semiconductor region is formed such that it has a side surface exhibiting such a current direction. By this rotation, the plane parallel to the substrate in the MISFET of this embodiment and the side surface of the protrusion in the n-type MISFET have a crystal orientation different from that in the reference state. Having such a crystal orientation, a CMIS can have improved carrier mobility properties. Furthermore, the n-type MISFET and the p-type MISFET are positioned such that their side surfaces of the protrusions are mutually orthogonal, so that an optimal arrangement in which layout of MISFETs are facilitated can be designed.

The plane parallel to the substrate in the MISFET in the reference state may be any of a (100) plane, a (010) plane and a (001) plane. With any of these planes as the plane parallel to the substrate, a crystal orientation of the side surfaces of the protrusions in the n-type and the p-type MISFETs is a {110} plane, these planes are mutually orthogonal, and rotation of these MISFETs by an identical angle gives an identical mobility because of symmetry of a silicon crystal.

For example, a rotation center is <011> in the reference state where a crystal orientation of the plane parallel to the substrate in the MISFET is a (100) plane, a crystal orientation of the side surface of the protrusion in the n-type MISFET is a (0-11) plane and a crystal orientation of the side surface of the protrusion in the p-type MISFET is a (011) plane. Furthermore, a rotation center is <101> in the reference state where a crystal orientation of the plane parallel to the substrate in the MISFET is a (010) plane, a crystal orientation of the side surface of the protrusion in the n-type MISFET is a (10-1) plane and a crystal orientation of the side surface of the protrusion in the p-type MISFET is a (101) plane. Furthermore, a rotation center is <110> in the reference state where a crystal orientation of the plane parallel to the substrate in the MISFET is a (001) plane, a crystal orientation of the side surface of the protrusion in the n-type MISFET is a (−110) plane and a crystal orientation of the side surface of the protrusion in the p-type MISFET is a (110) plane.

In the case of rotation around the normal line of the side surface of the protrusion in the p-type MISFET, as the rotation proceeds, crystal orientations of the side surface of the protrusion in the n-type MISFET and of the plane parallel to the substrate in the MISFET are changed. For the p-type MISFET, a plane direction of the side surface of the protrusion is unchanged while a crystal orientation of the plane parallel to the substrate is changed.

There will be described variation in carrier mobility properties when rotating the side surface of the protrusion in the n-type MISFET around the normal line of the side surface of the protrusion in the p-type MISFET from the reference state. FIG. 8(a) corresponds to the case where a rotation angle of the n-type MISFET indicates a mobility of 0 to 45° when rotation is conducted around the normal line of the substrate in FIG. 8(a).

In the reference state, a mobility in the n-type MISFET is represented by point (A) in FIG. 8(a) and a mobility in the p-type MISFET is represented by point (D) in FIG. 8(b). Here, a delay index of a CMIS determined is 8.8 from FIG. 9.

When rotating the side surface of the protrusion in the n-type MISFET by an angle of 90° or less centering around the normal line of the side surface of the protrusion in the p-type MISFET, a plane direction of the side surface of the protrusion in the p-type MISFET is unchanged while a crystal orientation of the plane parallel to the substrate is changed. Since a {110} plane is two-fold symmetric, a mobility varies depending on an in-plane current direction even when the plane direction is identical. Thus, a mobility in the p-type MISFET moves from point (D) to point (G) along the dotted line in FIG. 8(b). A carrier mobility in the n-type MISFET, starting from point (A) in FIG. 8(a), and reaches point (B) at a rotation angle of 90°. In the rotation centering around the normal line of the substrate, 45° rotation moves a mobility from point (A) to point (B) while in the rotation centering around the normal line of the side surface of the protrusion in the p-type MISFET, 90° rotation moves it from point (A) to point (B). Thus, rotation of the side surface of the protrusion gives a higher carrier mobility in the n-type MISFET-in comparison with rotation of the side surface of the protrusion centering around the normal line of the substrate. As a result, a delay index in a CMIS determined is reduced, so that improved carrier mobility properties can be achieved.

Preferably, the side surface of the protrusion in the n-type MISFET is rotated by 90°. FIG. 7 shows a semiconductor device with an arrangement after rotating the side surfaces of the protrusions in the n-type and the p-type MISFETs by 90° when the arrangement in FIG. 2 is a reference state. FIG. 7 shows the arrangement looked from <−110>. In this arrangement, a crystal orientation of the side surface of the protrusion in the n-type MISFET 2001 is a (001) plane, a crystal orientation of the side surface of the protrusion in the p-type MISFET 2002 is a (110) plane and a crystal orientation of the plane parallel to the substrate in the MISFET is a (−110) plane. Here, a mobility in the n-type MISFET is represented by point (B) in FIG. 8(a) and a mobility in the p-type MISFET is represented by point (G) in FIG. 8(b). From FIG. 9, a delay index in a CMIS determined is 6.1 (corresponding to the result in FIG. 6), which is lower than a delay index in a conventional CMIS corresponding to the arrangement in FIG. 2. Thus, carrier mobility properties in the CMIS are improved in comparison with a conventional CMIS.

Preferably, a crystal orientation of the side surface of the protruding semiconductor region in the p-type MISFET is substantially a {110} plane, and a crystal orientation of the side surface of the protruding semiconductor region in the n-type MISFET is substantially orthogonal to the {110} plane and a crystal orientation of the side surface is substantially different from the {110} plane. Here, a crystal orientation of the plane parallel to the substrate in the MISFET can be a {110} plane and a crystal orientation of the side surface of the protrusion in the p-type MISFET can be a {100} plane. Furthermore, from FIG. 8(c), a mobility in the p-type MISFET is maximum, so that a delay index in a CMIS can be reduced, resulting in a CMIS having excellent carrier mobility properties.

### EMBODIMENT 4

The following procedure can be conducted to obtain the comparable effects to Embodiment 1 where keeping parallel relationship between the side surfaces of protrusions in an n-type and a p-type MISFETs, the side surfaces of the protrusions in these MISFETs are rotated by an identical angle of 45°. Specifically, a reference state is the state where planes parallel to the substrate in the n-type and the p-type MISFETs are a {100} plane (including a surface with an off angle of 10° or less), crystal orientations of the side surfaces of the protrusions in the n-type and the p-type MISFETs are identical (the side surfaces of the protrusions are mutually parallel) and a crystal orientation of the side surface of the protrusion in this MISFET is a {100} plane perpendicular to the substrate. Embodiment 4 corresponds to the state after fixing or rotating planes parallel to the substrate in the n-type and the p-type MISFETs centering around the normal line of the side surfaces of the protrusions in the n-type and the p-type MISFETs by an angle of 0 to 90° both inclusive from the reference state.

As used herein, the phrase “rotating a plane parallel to a substrate” does not refer to actual rotation in a real space, but refers to changing a crystal orientation in a Fin by rotating the Fin within a crystal coordinate system while fixing the planar orientations of the side surfaces of the protrusions in the n-type and the p-type MISFETs.

In this embodiment, both of the surfaces which are to be channels in the n-type and the p-type MISFETs are fixed to a {100} plane and a current flow direction is changed only within the {100} plane. A mobility within the {100} plane is independent of a current flow direction because of four-fold symmetry of the crystal. This embodiment can provide comparable effects to Embodiment 1 where keeping parallel relationship between the side surfaces of protrusions in an n-type and a p-type MISFETs, the side surfaces of the protrusions in these MISFETs are rotated by an identical angle of 45°.

Process for Manufacturing a Semiconductor Device

A semiconductor device according to this invention can be manufactured by a process for manufacturing a conventional semiconductor device, except that a substrate having a different crystal orientation is used and a resist mask is formed in an arrangement after rotation by a given angle during photolithography.

FIG. 10 shows a process for manufacturing a semiconductor device having a fin-type MISFET in which a part of a protrusion is a part of a monocrystal silicon layer in an SOI substrate as shown in FIG. 12(b). First, bonding or SIMOX is performed an SOI substrate consisting of a silicon wafer substrate 3001, a SiO₂ oxide film 3002 and a monocrystal silicon film 3003. The monocrystal silicon film 3003 has a crystal orientation of a (100) plane in Embodiment 1 and a given crystal orientation in Embodiments 2 and 3. Then, in the surface of the SOI substrate is formed an SiO₂ film 3004 by thermal oxidation (FIG. 10(a)). Next, the monocrystal silicon film 3003 is doped by ion implanting to form a semiconductor region (FIG. 10(b)). Subsequently, the SiO₂ film 3004 is etched off (FIG. 10(c)). Alternatively, by omitting the step of ion implantation, an MISFET in which no dopants are intentionally introduced into a channel (non-doped channel MISFET) may be formed. Furthermore, the steps before and after the implantation, that is, forming a thermally oxidized film and removing the film can be omitted.

Next, a photoresist is applied over the whole surface of the monocrystal silicon film 3003, and photolithography is conducted to form a resist mask 3005 (FIG. 10(d)). Then, the monocrystal silicon film 3003 is anisotropically dry-etched using the resist mask 3005 as an etching mask and then the resist mask 3005 is removed to form a protrusion 3006 with a given height on the SiO₂ film 3002 (FIG. 10(e)). Here, the SiO₂ film can be appropriately etched back downward by anisotropic etching or downward and laterally by isotropic etching to form a π-gate type FinFET and a Ω-gate type FinFET, respectively.

Subsequently, a thin SiO₂ film 3007 is formed on the surface of the monocrystal silicon protrusion 3006 by thermal oxidation. Then, on the SiO₂ film 3007 is, by CVD, formed a polysilicon film, which is then made conductive by impurity diffusion and selectively etched into a given pattern to form a gate electrode 3008. Next, the monocrystal silicon protrusion 3006 is doped with an impurity using the gate electrode 3008 as a mask, to form a source and drain regions (FIG. 10(f)).

FIG. 11 shows a process for manufacturing a semiconductor device having a fin-type MISFET in which a part of a protrusion is a part of a silicon wafer substrate as shown in FIG. 12(a). First, on the surface of a monocrystal silicon film 3003 is formed an SiO₂ oxide film 3004 by thermal oxidation (FIG. 11(a)). The monocrystal silicon film 3003 has a crystal orientation of a (100) plane in Embodiment 1 and a given crystal orientation in Embodiments 2 and 3. Then, the monocrystal silicon film 3003 is doped by ion implantation to form a semiconductor region (FIG. 11(b)). Then, on the SiO₂ oxide film 3004 is formed a silicon nitride film 3009 by low-pressure CVD (FIG. 11(c)). Alternatively, by omitting the step of the above-described ion implantation, an MISFET in which no dopants are intentionally introduced into a channel (non-doped channel MISFET) may be formed. Furthermore, the steps before and after the implantation, that is, forming a thermally oxidized film and removing the film can be omitted.

Next, a photoresist is applied over the whole surface of the silicon nitride film 3009, and using photolithography, a resist mask 3005 is formed, leaving the photoresist only in the region where MOSFETs are to be formed (FIG. 11(d)). Then, the monocrystal silicon film 3003 is anisotropically dry-etched using the resist mask 3005 as an etching mask and then the resist mask 3005 is removed to form a protrusion 3006 with a given height on the substrate (FIG. 11(e)).

Subsequently, a SiO₂ film 3010 is formed by low-pressure CVD to a thickness such that the protrusion consisting of the protrusion 3006, the SiO₂ oxide film 3004 and the silicon nitride film 3009 is completely buried (FIG. 11(f)). Next, the SiO₂ oxide film 3010 is etched to a given thickness to form an insulating film 3011 for isolation (FIG. 11(h)).

Then, after, if necessary, removing the insulating films 3004 and 3009 over the protrusion, a thin SiO₂ oxide film 3007 is formed on the protrusion surface by thermal oxidation. Then, on the SiO₂ oxide film 3007 is, by CVD, formed a polysilicon film, which is then made conductive by impurity diffusion and selectively etched into a given pattern to form a gate electrode 3008. Next, the monocrystal silicon protrusion 3006 is doped with a dopant using the gate electrode 3008 as a mask, to form a source and drain regions (FIG. 11(f)).

In FIG. 11(g), without removing the insulating films over the protrusion, an insulating film thicker than the gate insulating film can be formed between the upper surface of the fin and the gate electrode 3008. Even when the fin is on the SOI, an insulating film thicker than the gate insulating film can be formed between the upper surface of the fin and the gate electrode as described above.

FIG. 17 show a process for manufacturing a semiconductor device having both a Fin-type MISFET and a planar type MISFET in combination (a bulk substrate type). The manufacturing course to an intermediate step (FIGS. 17(a) and (b)) is as described for the steps in FIGS. 11(a) to (f). Next, although the insulating film 3010 formed in the region other than the fin is etched back in the manufacturing in FIG. 11, the manufacturing process in FIG. 17 is different in that the insulating film 3010 is etched back in the region where a fin-type transistor is to be constituted while being not etched in the region where a planar type transistor is to be constituted (FIG. 17(c)).

Then, in the manufacturing process in FIG. 17, an insulating film is formed on the upper surface and the side surface of the fin in the region where a fin-type transistor is to be constituted and on the upper surface of the fin in the region where a planar type transistor is to be constituted. Furthermore, gate electrodes are formed such that the fin is sandwiched by them in the region where a fin-type transistor is to be constituted and on the upper surface of the fin in the region where a planar type transistor is to be constituted (FIG. 17(d)). FIG. 17(e) shows this mixed type transistor looked from the upper surface.

1. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:
that in terms of a crystal orientation of the protruding semiconductor region constituting the n-type field effect transistor, its plane parallel to a substrate is substantially a {100} plane and its side surface is substantially a {100} plane orthogonal to the {100} plane, and
that in terms of a crystal orientation of the protruding semiconductor region constituting the p-type field effect transistor, its plane parallel to the substrate is substantially a {100} plane.

2. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:
that in terms of a crystal orientation of the protruding semiconductor region constituting the p-type field effect transistor, its plane parallel to a substrate is substantially a {100} plane and its side surface is substantially a {110} plane orthogonal to the {100} plane, and
that in terms of a crystal orientation of the protruding semiconductor region constituting the n-type field effect transistor, its plane parallel to the substrate is substantially a {100} plane and its side surface is substantially different from a {110} plane orthogonal to the {100} plane.

3. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:
that in terms of a crystal orientation of the protruding semiconductor region constituting the n-type field effect transistor, its plane parallel to a substrate is substantially a {100} plane and its side surface is substantially a { 100} plane orthogonal to the {100} plane, and
that in terms of a crystal orientation of the protruding semiconductor region constituting the p-type field effect transistor, its plane parallel to the substrate is substantially a {100} plane and its side surface is substantially a {110} plane orthogonal to the {100} plane.

4. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:
that in terms of a crystal orientation of the protruding semiconductor region constituting the n-type field effect transistor, its side surface is substantially a {100} plane, and
that the side surface of the protruding semiconductor region constituting the p-type field effect transistor is substantially orthogonal to the {100} plane.

5. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:
that in terms of a crystal orientation of the protruding semiconductor region constituting the p-type field effect transistor, its side surface is substantially a {110} plane, and
that the side surface of the protruding semiconductor region constituting the n-type field effect transistor is substantially orthogonal to the {110} plane, and of the side surface is substantially different from a {110} plane.

6. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:
that in terms of a crystal orientation of the protruding semiconductor region constituting the n-type field effect transistor, its plane parallel to a substrate is substantially a {100} plane and its side surface is substantially a {100} plane orthogonal to the {110} plane, and
that in terms of a crystal orientation of the protruding semiconductor region constituting the p-type field effect transistor, its plane parallel to the substrate is substantially a {110} plane and its side surface is substantially a {110} plane orthogonal to the {110} plane.

7. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:
that in terms of a crystal orientation of the protruding semiconductor region constituting the n-type field effect transistor, its plane parallel to a substrate is substantially a {100} plane and its side surface is substantially orthogonal to the {100} plane and different from a {110} plane, and
that in terms of a crystal orientation of the protruding semiconductor region constituting the p-type field effect transistor, its plane parallel to the substrate is substantially a {100} plane and its side surface is substantially parallel or orthogonal to the side surface of the protruding semiconductor region constituting the n-type field effect transistor.

8. The semiconductor device as claimed in any of claims 1 to 7, wherein the planes parallel to the substrate in the protruding semiconductor regions constituting the n-type and the p-type field effect transistors have an identical crystal orientation.

9. The semiconductor device as claimed in any of claims 1 to 7, wherein the protruding semiconductor regions constituting the n-type and the p-type field effect transistors constitute a CMIS circuit.

10. A semiconductor device comprising an n-type and a p-type field effect transistors having a protruding semiconductor region whose plane parallel to a substrate has a crystal orientation of a {100} or {100} plane of less than 10° off and which has a channel in its side surface, a gate electrode formed at least on the side surface via an insulating film, and a source and a drain regions formed in the semiconductor region such that the gate electrode is sandwiched by the regions,
the n-type and the p-type field effect transistors have a crystal orientation obtained by independently fixing or rotating the side surfaces of the protrusions in the n-type and the p-type field effect transistors in a reference state to an angle of 0° to 90° both inclusive around the normal line of the substrate except the cases where both of the rotation angles of the n-type and the p-type field effect transistors are 0° or 90°,
wherein a state where the side surface of the protrusion in the n-type field effect transistor and the side surface of the protrusion in the p-type field effect transistor are {110} or {110} planes of less than 10° off perpendicular to the substrate is the reference state.

11. The semiconductor device as claimed in claim 10, wherein the n-type and the p-type field effect transistors have a crystal orientation obtained by rotating the side surfaces of the protrusions in the n-type and the p-type field effect transistors in the reference state by an equal angle.

12. The semiconductor device as claimed in claim 11, wherein both of the rotation angles from the reference state for the side surfaces of the protrusions in the n-type and the p-type field effect transistors are 45°.

13. The semiconductor device as claimed in claim 10, wherein the p-type field effect transistor has a crystal orientation obtained by fixing or rotating the side surface of the protrusion in the reference state by an angle of 0° to 10° both inclusive.

14. The semiconductor device as claimed in claim 13, wherein the rotation angle from the reference state for the side surface of the protrusion in the n-type field effect transistor is 45°.

15. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions,
the n-type and the p-type field effect transistors have a crystal orientation obtained by fixing or rotating the planes parallel to the substrate of the n-type and the p-type field effect transistors in the reference state and the side surface of the protrusion in the p-type field effect transistor in the reference state by an equal angle within the range of −45° to 45° both inclusive around the normal line of the side surface of the protrusion in the n-type field effect transistor,
wherein a state where the planes of protrusions parallel to the substrate and the side surfaces of the protrusions in the n-type and the p-type field effect transistors are mutually orthogonal {100} or {100} planes of less than 10° off is the reference state.

16. The semiconductor device as claimed in claim 15, wherein crystal orientations of the plane parallel to the substrate and of the side surface of the protrusion in the p-type field effect transistor are identical to crystal orientations of the plane parallel to the substrate in the reference state and of the side surface of the protrusion in the p-type field effect transistor in the reference state, respectively.

17. The semiconductor device as claimed in claim 15, wherein the rotation angle from the reference state for the plane parallel to the substrate and the side surface of the protrusion in the p-type field effect transistor is 45°.

18. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions,
the n-type and the p-type field effect transistors have a crystal orientation obtained by rotating the plane parallel to the substrate of the n-type and the p-type field effect transistors in the reference state and the side surface of the protrusion in the n-type field effect transistor in the reference state by an equal angle within the range of 90° or less around the normal line of the side surface of the protrusion in the p-type field effect transistor,
wherein a state where the planes of protrusions parallel to the substrate and the side surfaces of the protrusions in the n-type and the p-type field effect transistors are mutually orthogonal, and are a {100} or {100} planes of less than 10° off and {110} planes, respectively, is the reference state.

19. The semiconductor device as claimed in claim 18, wherein the rotation angle from the reference state for the plane parallel to the substrate and the side surface of the protrusion in the n-type field effect transistor is 90°.

20. A semiconductor device comprising an n-type and a p-type field effect transistors having a protruding semiconductor region with a channel in its side surface, a gate electrode formed at least on the side surface via an insulating film, and a source and a drain regions formed in the semiconductor region such that the gate electrode is sandwiched by the regions, meeting the conditions:
that in terms of a crystal orientation of the protruding semiconductor region constituting the n-type field effect transistor, its side surface is substantially a {100} plane, and that the side surface of the protruding semiconductor region constituting the p-type field effect transistor is substantially parallel to the {100} plane.

21. The semiconductor device as claimed in any of claims 1 to 3, 7 and 10 to 14,
wherein the semiconductor device further comprises a planar type field effect transistor having a semiconductor region on whose upper surface a main channel is formed, and
a crystal orientation of the planes parallel to the substrate in the protruding semiconductor region constituting the planar type field effect transistor, the protruding semiconductor region constituting the n-type field effect transistor and the protruding semiconductor region constituting the p-type field effect transistor are an identical (100) plane.

22. The semiconductor device as claimed in any of claims 1 to 7, and 10 to 20, wherein channel is further formed in the planes parallel to the substrate in the protruding semiconductor region constituting the n-type field effect transistor and in the protruding semiconductor region constituting the p-type field effect transistor.
